(19) United States
(12) Patent Application Publication
(10) Pub. No.: US 2025/0244404 A1
(43) Pub. Date: Jul. 31, 2025

(54) APPARATUS AND METHOD FOR DIAGNOSING BATTERY

(71) Applicant: LG ENERGY SOLUTION, LTD., Seoul (KR)

(72) Inventors: Yoon-Jung BAE, Daejeon (KR); Ju-Ri KIM, Daejeon (KR); Tae-In KIM, Daejeon (KR); Seon-Ho PAK, Daejeon (KR); Kyung-Eun SUN, Daejeon (KR); Hee-Seok JEONG, Daejeon (KR)

(21) Appl. No.: 19/042,897

(22) Filed: Jan. 31, 2025

(30) Foreign Application Priority Data
Jan. 31, 2024 (KR) 10-2024-0014967

(51) Int. Cl. G01R 31/392; B60L 58/16; G01R 31/3842; H01M 10/42

(52) U.S. Cl. CPC G01R 31/392; G01R 31/3842; H01M 10/4285; B60L 58/16; H01M 2220/20

(57) ABSTRACT

An apparatus for diagnosing a battery includes a profile obtaining unit configured to obtain a battery profile representing a corresponding relationship between voltage and capacity of a battery; and a control unit configured to divide a capacity section of the battery profile into a plurality of sections, derive a target value for any one target indicator among a plurality of diagnostic indicators preset in each section, compare a corresponding relationship between the derived plurality of target values with a reference profile preset to represent a corresponding relationship between the plurality of target indicators, and diagnose a state of the battery based on the comparison result.

### CROSS-REFERENCE TO RELATED APPLICATIONS

This application is based on and claims priority from Korean Patent Application No. 10-2024-0014967, filed on Jan. 31, 2024, with the Korean Intellectual Property Office, the disclosure of which is incorporated herein by reference in its entirety for all purposes as if fully set forth herein.

### TECHNICAL FIELD

The present disclosure relates to an apparatus and method for diagnosing a battery, and more particularly, to an apparatus and method for diagnosing a battery, which diagnoses a state of a battery.

### BACKGROUND

Recently, the demand for portable electronic products such as notebook computers, video cameras and portable telephones has increased sharply, and electric vehicles, energy storage batteries, robots, satellites and the like have been developed in earnest. Accordingly, high-performance batteries allowing repeated charging and discharging are being actively studied.

Examples of batteries that are commercially available at present include nickel-cadmium batteries, nickel hydrogen batteries, nickel-zinc batteries, lithium batteries and the like. Among them, lithium batteries are in the limelight since they have almost no memory effect compared to nickel-based batteries and also have very low self-charging rate and high energy density.

Although much research is being conducted on these batteries in terms of high capacity and high density, improving lifespan and safety is also important. In order to improve battery safety, technology that accurately diagnoses the current state of the battery is needed.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

Embodiments of the present disclosure are designed to at least partly address, and even solve the problems of the related art, and therefore aspects of the present disclosure are directed to providing an apparatus and method for diagnosing a battery, which diagnoses a state of a battery and control the battery according to the diagnosis result.

These and other objects and advantages of the present disclosure may be understood from the following detailed description and will become more fully apparent from the exemplary embodiments of the present disclosure. Also, it will be easily understood that the objects and advantages of the present disclosure may be realized by the means shown in the appended claims and combinations thereof.

An apparatus for diagnosing a battery according to one aspect of the present disclosure may comprise a profile obtaining unit configured to obtain a battery profile representing a corresponding relationship between voltage and capacity of a battery; and a control unit configured to divide a capacity section of the battery profile into a plurality of sections, derive a target value for any one target indicator among a plurality of diagnostic indicators preset in each section, compare a corresponding relationship between the derived plurality of target values with a reference profile preset to represent a corresponding relationship between the plurality of target indicators, and diagnose a state of the battery based on the comparison result.

The control unit may be configured to diagnose the state of the battery as a positive/negative electrode degradation state when a target point representing the corresponding relationship between the plurality of target values is included in the reference profile.

The control unit may be configured to diagnose the state of the battery as a negative electrode degradation state when the target point is included in a first region based on the reference profile.

The control unit may be configured to diagnose the state of the battery as a positive electrode degradation state when the target point is included in a second region based on the reference profile.

The control unit may be configured to diagnose the state of the battery as an end of life (EOL) state when the target point is included in a third region.

The third region may be preset as a region that exceeds a preset threshold value for each of the plurality of target indicators.

The control unit may be configured to reduce at least one of an upper limit C-rate and a constant voltage charge time set for the battery when the state of the battery is diagnosed as the positive electrode degradation state or the positive/negative electrode degradation state.

The control unit may be configured to reduce a charge upper limit voltage set for the battery when the state of the battery is diagnosed as the negative electrode degradation state or the positive/negative electrode degradation state.

The control unit may be configured to divide the capacity section into a first section and a second section based on a preset division ratio or target capacity.

The profile obtaining unit may be configured to obtain a differential profile corresponding to the battery profile.

The control unit may be configured to determine a main peak from the differential profile and divide the capacity section based on a capacity of the determined main peak.

The differential profile may represent a corresponding relationship between the capacity and a differential voltage of the battery.

The control unit may be configured to determine a plurality of minimum points in the differential profile, and determine a minimum point with a smallest corresponding differential voltage as a main peak among the determined plurality of minimum points.

The differential profile may represent a corresponding relationship between the voltage and a differential capacity of the battery.

The control unit may be configured to determine a plurality of maximum points in the differential profile, and determine a maximum point with a largest corresponding differential voltage as a main peak among the determined plurality of maximum points.

A battery pack according to another aspect of the present disclosure may comprise the apparatus for diagnosing a battery according to one aspect of the present disclosure.

A vehicle according to still another aspect of the present disclosure may comprise the apparatus for diagnosing a battery according to one aspect of the present disclosure.

A method for diagnosing a battery according to still another aspect of the present disclosure may comprise a profile obtaining step of obtaining a battery profile representing a corresponding relationship between voltage and capacity of a battery; a section dividing step of dividing a capacity section of the battery profile into a plurality of sections; a target value deriving step of deriving a target value for any one target indicator among a plurality of diagnostic indicators preset in each section; a comparing step of comparing a corresponding relationship between the derived plurality of target values with a reference profile preset to represent a corresponding relationship between the plurality of target indicators; and a diagnosing step of diagnosing a state of the battery based on the comparison result.

The method may comprise diagnosing the state of the battery as a positive/negative electrode degradation state when a target point representing the corresponding relationship between the plurality of target values is included in the reference profile, diagnosing the state of the battery as a negative electrode degradation state when the target point is included in a first region based on the reference profile, and diagnosing the state of the battery as a positive electrode degradation state when the target point is included in a second region based on the reference profile.

The method may comprise diagnosing the state of the battery as an end of life (EOL) state when the target point is included in a third region, wherein the third region is preset as a region that exceeds a preset threshold value for each of the plurality of target indicators.

The method may comprise reducing at least one of an upper limit C-rate and a constant voltage charge time set for the battery when the state of the battery is diagnosed as the positive electrode degradation state or the positive/negative electrode degradation state.

The method may comprise reducing a charge upper limit voltage set for the battery when the state of the battery is diagnosed as the negative electrode degradation state or the positive/negative electrode degradation state.

The method may comprise dividing the capacity section into a first section and a second section based on a preset division ratio or target capacity.

The method may comprise obtaining a differential profile corresponding to the battery profile, and determining a main peak from the differential profile and dividing the capacity section based on a capacity of the determined main peak.

According to certain aspects, the differential profile may represent a corresponding relationship between the capacity and a differential voltage of the battery, and the method may further comprise determining a plurality of minimum points in the differential profile, and determining a minimum point with a smallest corresponding differential voltage as a main peak among the determined plurality of minimum points.

According to certain aspects, the differential profile may represent a corresponding relationship between the voltage and a differential capacity of the battery, and the method may further comprise determining a plurality of maximum points in the differential profile, and determining a maximum point with a largest corresponding differential voltage as a main peak among the determined plurality of maximum points.

According to one aspect of the present disclosure, there is an advantage in that the state of the battery may be diagnosed from various aspects depending on the combination of various target indicators.

In particular, according to certain embodiments, since the target value for each section is a value representing the state of the battery corresponding to the section, the state of the battery may be more specifically separated and diagnosed based on the corresponding relationship of a plurality of target values.

The effects of embodiments of the present disclosure are not limited to the effects mentioned above, and other effects not mentioned will be clearly understood by those skilled in the art from the description of the claims.

### DESCRIPTION OF DRAWINGS

The accompanying drawings illustrate preferred embodiments of the present disclosure and together with the foregoing disclosure, serve to provide further understanding of the technical features of the present disclosure, and thus, the present disclosure is not construed as being limited to the drawings.

FIG. 1 is a diagram schematically showing an apparatus for diagnosing a battery according to an embodiment of the present disclosure.

FIG. 2 is a schematic drawing of a battery profile according to an embodiment of the present disclosure.

FIG. 3 is a schematic drawing of a plurality of target indicators according to an embodiment of the present disclosure.

FIG. 4 is a schematic drawing of a reference profile according to an embodiment of the present disclosure.

FIG. 5 is a schematic drawing of a differential profile according to an embodiment of the present disclosure.

FIG. 6 is a schematic drawing of a battery pack according to another embodiment of the present disclosure.

FIG. 7 is a drawing schematically showing a vehicle according to still another embodiment of the present disclosure.

FIG. 8 is a diagram schematically showing a method for diagnosing a battery according to still another embodiment of the present disclosure.

### DETAILED DESCRIPTION

It should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the description proposed herein is just a preferable example for the purpose of illustrations only, not intended to limit the scope of the disclosure, so it should be understood that other equivalents and modifications could be made thereto without departing from the scope of the disclosure.

Additionally, in describing the present disclosure, when it is deemed that a detailed description of relevant known elements or functions renders the key subject matter of the present disclosure ambiguous, the detailed description is omitted herein.

The terms including the ordinal number such as “first”, “second” and the like, may be used to distinguish one element from another among various elements, but not intended to limit the elements by the terms.

Throughout the specification, when a portion is referred to as “comprising” or “including” any element, it means that the portion may include other elements further, without excluding other elements, unless specifically stated otherwise.

In addition, throughout the specification, when a portion is referred to as being “connected” to another portion, it is not limited to the case that they are “directly connected”, but it also includes the case where they are “indirectly connected” with another element being interposed between them.

Hereinafter, preferred embodiments of the present disclosure will be described in detail with reference to the accompanying drawings.

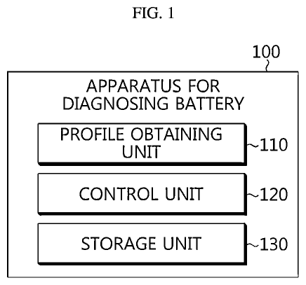

FIG. 1 is a diagram schematically illustrating an apparatus 100 for diagnosing a battery according to an embodiment of the present disclosure.

Referring to FIG. 1, the apparatus 100 for diagnosing a battery may include a profile obtaining unit 110, a control unit 120, and a storage unit 130.

Here, the battery refers to an independent cell that has a negative terminal and a positive terminal and is physically separable. As an example, a lithium-ion battery or a lithium polymer battery may be considered as a battery. In addition, the type of batteries may be a cylindrical type, a prismatic type or a pouch type. Additionally, the battery may mean a battery bank, a battery module or a battery pack in which a plurality of cells are connected in series and/or parallel. Below, for convenience of explanation, the battery is explained as meaning one independent cell.

The profile obtaining unit 110 may be configured to obtain a battery profile BP representing a corresponding relationship between voltage and capacity of the battery.

For example, the battery profile BP is a profile representing the corresponding relationship between voltage V and capacity Q when the capacity of the battery is charged from a preset charge start capacity, or 0%, to a preset charge end capacity, or 100%. As another example, the battery profile BP may represent the corresponding relationship between voltage V and capacity Q when the battery is discharged from the preset discharge start capacity, or 100%, to the preset discharge end capacity, or 0%.

For example, there is no special limitation on the C-rate in charging or discharging for generating the battery profile BP. However, preferably, the battery should be charged or discharged at a low rate in order to obtain a more accurate battery profile BP and differential profile. For example, the battery profile BP may be generated in the process of charging or discharging the battery at 0.05 C.

For example, the profile obtaining unit 110 may directly receive the battery profile BP of the battery from the outside. That is, the profile obtaining unit 110 may obtain the battery profile BP by being connected to the outside via wire and/or wirelessly and receiving the battery profile BP.

As another example, the profile obtaining unit 110 may receive the battery information about the voltage and capacity of the battery. Then, the profile obtaining unit 110 may generate a battery profile BP based on the received battery information. That is, the profile obtaining unit 110 may obtain the battery profile BP by directly generating the battery profile BP based on the battery information.

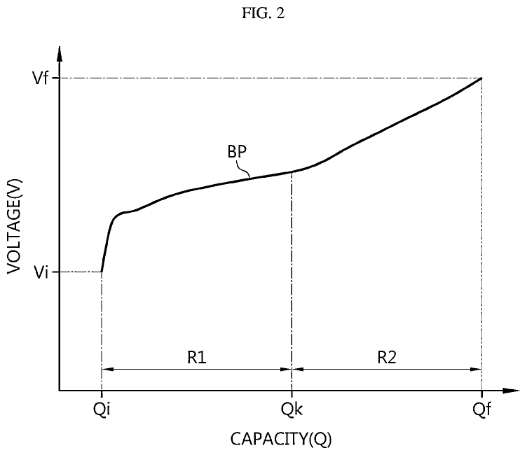

FIG. 2 is a schematic drawing of a battery profile BP according to an embodiment of the present disclosure. In the embodiment of FIG. 2, the battery profile BP may be expressed as an X-Y graph in which the X-axis is set to capacity Q and the Y-axis is set to voltage V.

The profile obtaining unit 110 may be connected to communicate with the control unit 120. For example, the profile obtaining unit 110 may be connected to the control unit 120 by wire and/or wirelessly. The profile obtaining unit may transmit the obtained battery profile BP to the control unit 120.

The control unit 120 may be configured to divide the capacity section of the battery profile BP into a plurality of sections.

Specifically, the control unit 120 may divide the entire capacity section of the battery profile BP into two or more sections. For example, in the embodiment of FIG. 2, the capacity sections of the battery profile BP are Qi to Qf. The control unit 120 may divide the capacity sections of Qi to Qf into the first section R1 and the second section R2 based on Qk.

The control unit 120 may be configured to derive a target value for any one target indicator among a plurality of diagnostic indicators preset in each section.

Specifically, a plurality of diagnostic indicators may be preset for each of the plurality of sections. Here, the diagnostic indicator is an indicator representing the state of the battery in the corresponding section and may be used to diagnose the state of the battery in the corresponding section. For example, since there are unique indicators that can only be derived from each of the plurality of sections, some or all of the diagnostic indicators set for each of the plurality of sections may be different.

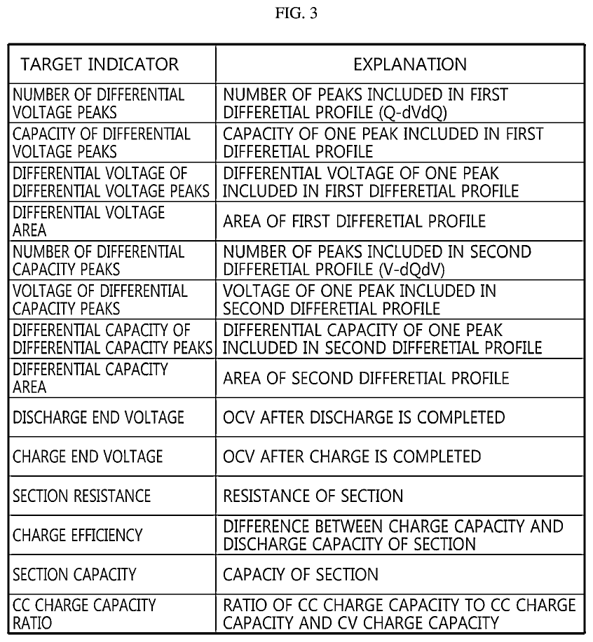

FIG. 3 is a schematic drawing of a plurality of target indicators according to an embodiment of the present disclosure.

(1) The number of differential voltage peaks is the number of peaks included in the corresponding section of the first differential profile. For example, the number of maximum points and/or minimum points included in the corresponding section of the first differential profile may be determined as the number of differential voltage peaks.

Here, the differential voltage peak means a peak included in the first differential profile in which the battery profile BP is differentiated with respect to the capacity. For example, when the battery profile BP is differentiated with respect to the capacity, a first differential profile representing a corresponding relationship between the capacity Q and the differential voltage dV/dQ may be derived. And, the first differential profile may include a plurality of differential voltage peaks. Here, the differential voltage peak means a maximum point and/or a minimum point included in the first differential profile.

(2) The capacity of the differential voltage peak is the capacity of the target peak included in the corresponding section of the first differential profile. For example, the peak with the largest corresponding differential voltage among one or more maximum points included in the corresponding section of the first differential profile may be determined as the target peak. The target peak may be changed depending on the state of the battery to be diagnosed.

(3) The differential voltage of the differential voltage peak is the differential voltage of the target peak included in the corresponding section of the first differential profile.

(4) The differential voltage area is the area of the corresponding section of the first differential profile. The value of the corresponding section of the first differential profile integrated with respect to the capacity may be determined as the differential voltage area.

(5) The number of differential capacity peaks is the number of peaks included in the corresponding section of the second differential profile. For example, the number of maximum points and/or minimum points included in the corresponding section of the second differential profile may be determined as the number of differential voltage peaks.

Here, the differential capacity peak means a peak included in the second differential profile, which is obtained by differentiating the battery profile BP with respect to the voltage. For example, when the battery profile BP is differentiated with respect to the voltage, a second differential profile representing the corresponding relationship between the voltage V and the differential capacity dQ/dV may be derived. In addition, the second differential profile may include a plurality of differential capacity peaks. Here, the differential capacity peak means a maximum point and/or a minimum point included in the second differential profile.

(6) The capacity of the differential capacity peak is the capacity of the target peak included in the corresponding section of the second differential profile. For example, the peak with the largest corresponding differential voltage among one or more maximum points included in the corresponding section of the second differential profile may be determined as the target peak. The target peak may be changed depending on the state of the battery to be diagnosed.

(7) The differential capacity of the differential capacity peak is the differential capacity of the target peak included in the corresponding section of the second differential profile.

(8) The differential capacity area is the area of the corresponding section of the second differential profile. The integrated value of the corresponding section of the second differential profile with respect to voltage may be determined as the differential capacity area.

(9) The discharge end voltage refers to the OCV (open circuit voltage) after the discharge of the battery is completed. Since the discharge end voltage may be derived when the discharge of the battery is completed, it is a diagnostic indicator that may be derived only in the low capacity section. Specifically, the discharge end voltage may be derived in the low capacity section corresponding to the voltage set to terminate the discharge of the battery.

(10) The charge end voltage refers to the OCV after the charge of the battery is terminated. Since the charge end voltage may be derived when the charge of the battery is terminated, it is a diagnostic indicator that may be derived only in the high capacity section. Specifically, the charge end voltage may be derived in the high capacity section corresponding to the voltage set to terminate the charge of the battery.

(11) The section resistance means the ratio of voltage change amount to the charge/discharge current of the corresponding section.

(12) The charge efficiency means the difference between the charge capacity and the discharge capacity. For example, the charge efficiency of the low-capacity section in the nth cycle may be calculated according to the formula of “charge capacity of the nth cycle-discharge capacity of the nth cycle.” And, the charge efficiency of the high-capacity section in the nth cycle may be calculated according to the formula of “discharge capacity of the nth cycle-charge capacity of the n+1th cycle.” In other words, the charge efficiency is not limited to the corresponding section, but may be calculated according to the entire charge/discharge capacity of the cycle.

(13) The section capacity refers to the capacity of the section.

(14) The CC charge capacity ratio refers to the ratio of the CC charge capacity to the CC (constant current) charge capacity and the CV (constant voltage) charge capacity. Since the CV charge is performed at the end of the charge, the CC charge capacity ratio is a diagnostic indicator that may be derived only in the high-capacity section. Specifically, the CC charge capacity ratio may be derived in the high-capacity section corresponding to the voltage set to terminate the charge of the battery.

The control unit 120 may be configured to compare the corresponding relationship between the derived plurality of target values with a preset reference profile representing the corresponding relationship between the plurality of target indicators.

Specifically, if it is assumed that the capacity section of the battery profile BP is divided into the first section R1 and the second section R2, the first target value for the target indicator is derived from the first section R1, and the second target value for the target indicator is derived from the second section R2. The control unit 120 may compare a target point representing the corresponding relationship of the plurality of target values with the reference profile.

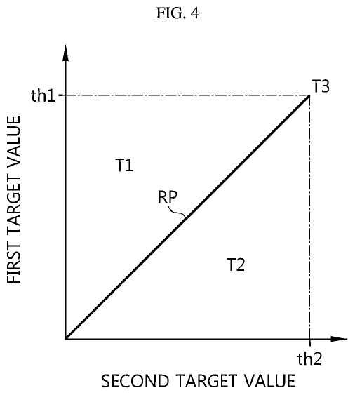

FIG. 4 is a schematic drawing of a reference profile according to an embodiment of the present disclosure. In the embodiment of FIG. 4, the reference profile may be expressed as an X-Y graph in which the X-axis is set to the second target value and the Y-axis is set to the first target value.

Specifically, the control unit 120 may determine whether the target point is included in the reference profile. If the target point is not included in the reference profile, the control unit 120 may determine which region among the first region T1, the second region T2, and the third region T3 the target point is included in.

Here, the first region T1 is a region in which the first target value is greater based on the reference profile. For example, in the embodiment of FIG. 4, the first region T1 is a region in which the first target value of the target point exceeds the first target value of the reference profile based on the same second target value.

Here, the second region T2 is a region in which the second target value is greater based on the reference profile. For example, in the embodiment of FIG. 4, the second region T2 is a region in which the second target value of the target point exceeds the second target value of the reference profile based on the same first target value.

Here, the third region T3 may be configured to be preset as a region that exceeds a threshold value preset for each of the plurality of target indicators. The threshold value may be independently set for each of the first target value and the second target value. For example, in the embodiment of FIG. 4, the third region T3 is a region in which the first feature value of the target point exceeds the first threshold value (th1) and the second feature value of the target point exceeds the second threshold value (th2).

That is, in the embodiment of FIG. 4, the target point may be included in the reference profile, the first region T1, the second region T2, or the third region T3.

The control unit 120 may be configured to diagnose the state of the battery based on the comparison result.

For example, the control unit 120 may be configured to diagnose the state of the battery as a positive/negative electrode degradation state if the target point representing the corresponding relationship between the plurality of target values is included in the reference profile. Here, the positive/negative electrode degradation state is a state in which both the positive electrode and the negative electrode of the battery are degraded, and is a state in which the degradation degrees of the positive electrode and the negative electrode are balanced.

As another example, the control unit 120 may be configured to diagnose the state of the battery as a negative electrode degradation state if the target point is included in the first region T1 based on the reference profile. Here, the negative electrode degradation state is a state in which the degradation of the negative electrode of the battery is more dominant than the degradation of the positive electrode. In other words, the negative electrode degradation state is a state in which the degradation of the positive electrode and the negative electrode are not balanced, and the degradation of the negative electrode progresses more than the degradation of the positive electrode. For example, the negative electrode degradation state is related to the loss of available lithium. When available lithium is lost, lithium plating, in which lithium metal is deposited on the surface of the negative electrode, may occur.

As another example, the control unit 120 may be configured to diagnose the state of the battery as a positive electrode degradation state if the target point is included in the second region T2 based on the reference profile. Here, the positive electrode degradation state is a state in which the positive electrode of the battery is degraded, and the degradation of the positive electrode is more dominant than the degradation of the negative electrode. In other words, the positive electrode degradation state is a state in which the degradation of the positive electrode and the negative electrode are not balanced, and the degradation of the positive electrode progresses more than the degradation of the negative electrode.

As still another example, the control unit 120 may be configured to diagnose the state of the battery as an EOL (end of life) state if the target point is included in the third region T3. Here, the EOL state means a state in which the battery is significantly degraded and use of the battery is not recommended. For example, the EOL state may be a state in which the battery may be determined to be an unusable state.

The apparatus 100 for diagnosing a battery according to an embodiment of the present disclosure may diagnose the state of the battery according to the corresponding relationship of the target values calculated from each of the plurality of sections. That is, according to an embodiment of the present disclosure, there is an advantage in that the state of the battery may be diagnosed from various aspects according to the combination of various target indicators.

In particular, since the target value for each section may be a value representing the state of the battery corresponding to the section, the state of the battery may be more specifically separated and diagnosed based on the corresponding relationship of the plurality of target values.

Meanwhile, the profile obtaining unit 110 and the control unit 120 included in the apparatus 100 for diagnosing a battery may optionally include processors, application-specific integrated circuits (ASICs), other chipsets, logic circuits, registers, communication modems, data processing devices, etc. known in the art to execute various control logics performed in the present disclosure. Also, when the control logic is implemented as software, the profile obtaining unit 110 and the control unit 120 may be implemented as a set of program modules. At this time, the program module may be stored in the memory and executed by the profile obtaining unit 110 and the control unit 120. The memory may be inside or outside the profile obtaining unit 110 and the control unit 120 and may be connected to the profile obtaining unit 110 and the control unit 120 by various well-known means.

In addition, the apparatus 100 for diagnosing a battery may further include a storage unit 130. The storage unit 130 may store data necessary for operation and function of each component of the apparatus 100 for diagnosing a battery, data generated in the process of performing the operation or function, or the like. The storage unit 130 is not particularly limited in its kind as long as it is a known information storage means that can record, erase, update and read data. As an example, the information storage means may include RAM, flash memory, ROM, EEPROM, registers, and the like. In addition, the storage unit 130 may store program codes in which processes executable by the profile obtaining unit 110 and the control unit 120 are defined.

For example, the storage unit 130 may store the battery information, the battery profile BP, the differential profile, and the battery diagnosis information by the control unit 120.

The control unit 120 may be configured to control the battery based on the diagnosis result regarding the state of the battery. Specifically, the control unit 120 may change the usage conditions of the battery based on the diagnosis result.

The control unit 120 may be configured to reduce at least one of an upper limit C-rate and a constant voltage charge time set for the battery when the state of the battery is diagnosed as a positive electrode degradation state or a positive/negative electrode degradation state. That is, when the control unit 120 diagnoses that the positive electrode of the battery is degraded, the control unit 120 may change the usage conditions of the battery to prevent the positive electrode of the battery from being further degraded.

The control unit 120 may be configured to reduce the charge upper limit voltage set for the battery when the state of the battery is diagnosed as a negative electrode degradation state or a positive/negative electrode degradation state. When the control unit 120 diagnoses that the negative electrode of the battery is degraded, the control unit 120 may change the usage conditions of the battery to prevent the negative electrode of the battery from being further degraded.

As the usage conditions of the battery change, the deterioration of the positive electrode and/or negative electrode of the battery may be slowed, thereby increasing the expected life of the battery.

The control unit 120 may be configured to divide the capacity section into a first section R1 and a second section R2 based on a preset division ratio or target capacity.

In one embodiment, the control unit 120 may divide the capacity section based on a preset ratio. For example, the control unit 120 may divide the capacity section in a ratio of n:m (where n and m are positive numbers) to set the lower capacity section as the first section R1 and set the upper capacity section as the second section R2.

For example, assume that the start capacity is Qi and the end capacity is Qf. In addition, assume that the capacity corresponding to the ratio of n:m is Qk, and Qk may be calculated according to the formula of “(Qf−Qi)÷(n+m)×n”. The control unit 120 may set the capacity section of Qi to Qk as the first section R1. And, the control unit 120 may set the capacity section of Qk to Qf as the second section R2.

In another embodiment, the control unit 120 may distinguish the capacity section using the differential profile based on the battery profile BP.

The profile obtaining unit 110 may be configured to further obtain a differential profile corresponding to the battery profile.

For example, when the battery profile BP is differentiated with respect to the capacity, a differential profile may be generated that represents the corresponding relationship between the differential voltage dV/dQ and the capacity Q. Conversely, when the battery profile BP is differentiated with respect to the voltage, a differential profile may be generated that represents the corresponding relationship between the differential capacity dQ/dV and the voltage V.

For example, the profile obtaining unit 110 may directly receive the differential profile of the battery from the outside. That is, the profile obtaining unit 110 may obtain the differential profile by being connected to the outside by wire and/or wirelessly and receiving the differential profile.

As another example, the profile obtaining unit 110 may directly receive the battery profile BP of the battery from the outside. Then, the profile obtaining unit 110 may generate a differential profile based on the battery profile BP. That is, the profile obtaining unit 110 may obtain a differential profile by receiving the battery profile BP through a wired and/or wireless connection to the outside, and directly generating a differential profile from the battery profile BP.

As still another example, the profile obtaining unit 110 may receive battery information about the voltage and capacity of the battery. Then, the profile obtaining unit 110 may generate a battery profile BP based on the received battery information, and generate a differential profile based on the generated battery profile BP. That is, the profile obtaining unit 110 may obtain a differential profile by directly generating the differential profile based on the battery information.

The profile obtaining unit 110 may be connected to communicate with the control unit 120. For example, the profile obtaining unit 110 may be connected to the control unit 120 by wire and/or wirelessly. The profile obtaining unit may transmit the obtained differential profile DP to the control unit 120.

In one embodiment, the differential profile DP obtained by the profile obtaining unit 110 may be configured to represent a corresponding relationship between the capacity Q and the differential voltage dV/dQ of the battery.

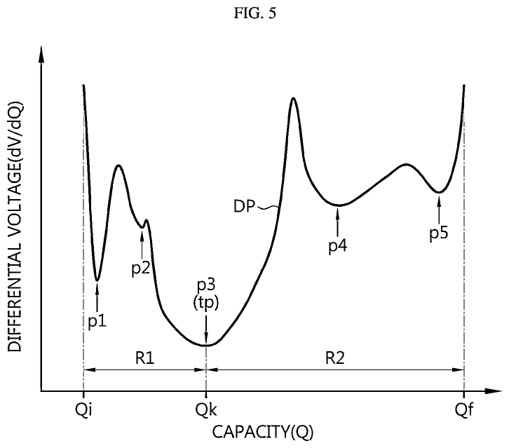

FIG. 5 is a schematic drawing of a differential profile DP according to an embodiment of the present disclosure. In the embodiment of FIG. 5, the differential profile DP may be expressed as an X-Y graph in which the X-axis is set to capacity Q and the Y-axis is set to differential voltage dV/dQ. For example, the differential profile DP of FIG. 5 has the same shape as the first differential profile of FIG. 3.

The control unit 120 may be configured to determine the main peak (tp) in the differential profile DP.

Specifically, the control unit 120 may be configured to determine a plurality of minimum points in the differential profile DP. For example, in the embodiment of FIG. 5, the differential profile DP may include first to fifth minimum points (p1, p2, p3, p4, p5).

Also, the control unit 120 may be configured to determine the minimum point with the smallest corresponding differential voltage among the determined plurality of minimum points as the main peak (tp). For example, in the embodiment of FIG. 5, since the differential voltage corresponding to the third minimum point (p3) among the plurality of minimum points (p1, p2, p3, p4, p5) is the smallest, the control unit 120 may determine the third minimum point (p3) as the main peak (tp).

The control unit 120 may be configured to divide the capacity section based on the capacity of the determined main peak (tp). For example, in the embodiment of FIG. 5, if the capacity of the main peak (tp) is Qk, the control unit 120 may divide the capacity section into a first section R1 of Qi to Qk and a second section R2 of Qk to Qf.

Generally, based on the minimum point where the differential voltage is the smallest, the low capacity side reflects the state of the negative electrode of the battery, and the high capacity side reflects the state of the positive electrode of the battery. Therefore, the control unit 120 may divide the capacity section of the battery not only based on a certain ratio (n:m) but also based on the main peak (tp).

More preferably, the control unit 120 may determine a minimum point that is included in a lower-middle capacity section of the battery and has the smallest corresponding differential voltage as the main peak (tp).

In general, if the capacity section of a battery is divided into a low capacity section and a high capacity section, the minimum point with the smallest differential voltage is included in the low capacity section. Therefore, the control unit 120 may determine the main peak (tp) in the middle or lower capacity section (low capacity section) of the battery. That is, the control unit 120 may save time and system resources required to determine the main peak (tp) by determining the main peak (tp) among a plurality of minimum points included in the low capacity section.

For example, in the embodiment of FIG. 5, the low-capacity section includes first to third minimum points (p1, p2, p3). The control unit 120 may determine the third minimum point (p3) with the smallest differential voltage among the first to third minimum points (p1, p2, p3) as the main peak (tp).

That is, since the total capacity section and the low-capacity section have different numbers of minimum points, the time and system resources required to compare the differential voltage of the plurality of minimum points may also be different. Therefore, the control unit may determine the main peak more quickly by considering only the minimum points included in the low-capacity section.

In another embodiment, the differential profile obtained by the profile obtaining unit 110 may represent a corresponding relationship between the voltage V and the differential capacity dQ/dV of the battery.

The control unit 120 may be configured to determine a plurality of maximum points in the differential profile. The maximum point is a concept opposite to the minimum point, and refers to a point in the differential profile that has an upward convex shape.

In addition, the control unit 120 may be configured to determine a maximum point having the largest corresponding differential voltage among the determined plurality of maximum points as the main peak.

The apparatus 100 for diagnosing a battery according to embodiments of the present disclosure may be applied to a battery management system (BMS). That is, the BMS according to the embodiments of the present disclosure may include the apparatus 100 for diagnosing a battery described above. In this configuration, at least some of components of the apparatus 100 for diagnosing a battery may be implemented by supplementing or adding functions of the components included in a conventional BMS. For example, the profile obtaining unit 110, the control unit 120 and the storage unit 130 of the apparatus 100 for diagnosing a battery may be implemented as components of the BMS.

Additionally, the apparatus 100 for diagnosing a battery according to embodiments of the present disclosure may be provided in the battery pack. That is, the battery pack according to embodiments of the present disclosure may include the above-described apparatus 100 for diagnosing a battery and at least one battery cell. Additionally, the battery pack may further include electrical components (relays, fuses, etc.) and a case.

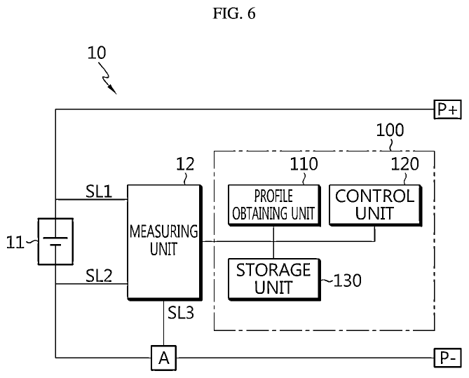

FIG. 6 is a drawing schematically showing a battery pack 10 according to another embodiment of the present disclosure.

The positive electrode terminal of the battery 11 may be connected to the positive electrode terminal P+ of the battery pack 10, and the negative electrode terminal of the battery 11 may be connected to the negative electrode terminal P− of the battery pack 10.

The measuring unit 12 may be connected to the first sensing line SL1, the second sensing line SL2, and the third sensing line SL3. Specifically, the measuring unit 12 may be connected to the positive electrode terminal of the battery 11 through the first sensing line SL1 and connected to the negative electrode terminal of the battery 11 through the second sensing line SL2. The measuring unit 12 may measure the voltage of the battery 11 based on the voltage measured at each of the first sensing line SL1 and the second sensing line SL2.

Also, the measuring unit 12 may be connected to the current measuring unit A through the third sensing line SL3. For example, the current measuring unit A may be an ammeter or a shunt resistor capable of measuring the charging current and the discharging current of the battery 11. The measuring unit 12 may measure the charging current of the battery 11 through the third sensing line SL3 to calculate the charge amount. In addition, the measuring unit 12 may measure the discharging current of the battery 11 through the third sensing line SL3 to calculate the discharge amount.

For example, the profile obtaining unit 110 may receive battery information about the voltage and current of the battery from the measuring unit 12. Then, the profile obtaining unit 110 may generate a battery profile BP and a differential profile based on the battery information.

As another example, the profile obtaining unit 110 may receive the battery profile BP from the measuring unit 12. Then, the profile obtaining unit 110 may generate a differential profile based on the battery profile BP.

As still another example, the profile obtaining unit 110 may receive a differential profile from the measuring unit 12.

An external device may be connected to the positive electrode terminal P+ and the negative electrode terminal P− of the battery pack 10. For example, the external device may be a charging device or a load. In addition, the positive electrode terminal of the battery 11, the positive electrode terminal P+ of the battery pack 10, the external device, the negative electrode terminal P− of the battery pack 10, and the negative electrode terminal of the battery 11 may be electrically connected.

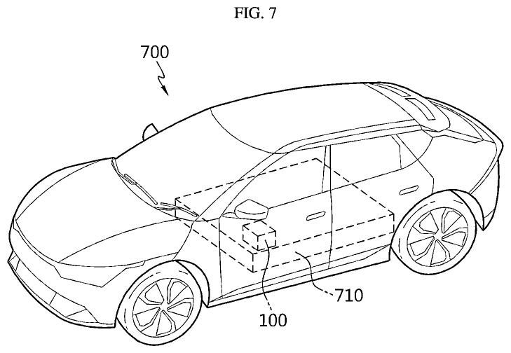

FIG. 7 is a drawing schematically showing a vehicle 700 according to still another embodiment of the present disclosure.

Referring to FIG. 7, the battery pack 710 according to the embodiment of the present disclosure may be included in a vehicle 700, such as an electric vehicle (EV) or a hybrid vehicle (HV). In addition, the battery pack 710 may drive the vehicle 700 by supplying power to a motor through an inverter provided in the vehicle 700. Here, the battery pack 710 may include the apparatus 100 for diagnosing a battery. That is, the vehicle 700 may include the apparatus 100 for diagnosing a battery. In this case, the apparatus 100 for diagnosing a battery may be an onboard device included in the vehicle 700.

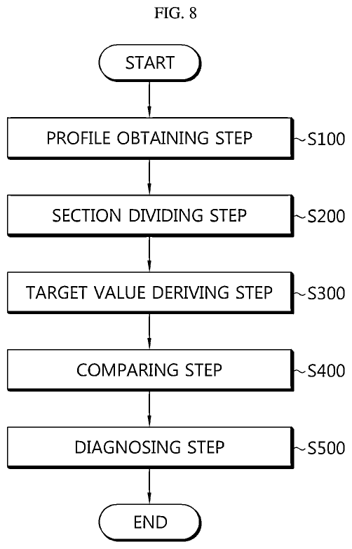

FIG. 8 is a diagram schematically showing a method for diagnosing a battery according to still another embodiment of the present disclosure.

Referring to FIG. 8, the method for diagnosing a battery may include a profile obtaining step (S100), a section dividing step (S200), a target value deriving step (S300), a comparing step (S400), and a diagnosing step (S500).

Preferably, each step of the method for diagnosing a battery may be performed by the apparatus 100 for diagnosing a battery. Hereinafter, for convenience of explanation, content that overlaps with the content described above will be omitted or briefly described.

The profile obtaining step (S100) is a step of obtaining a battery profile BP representing a corresponding relationship between voltage and capacity of a battery, and may be performed by the profile obtaining unit 110.

For example, the profile obtaining unit 110 may directly receive the battery profile BP of the battery from the outside. That is, the profile obtaining unit 110 may obtain the battery profile BP by being connected to the outside via wire and/or wirelessly and receiving the battery profile BP.

As another example, the profile obtaining unit 110 may receive battery information about the voltage and capacity of the battery. Then, the profile obtaining unit 110 may generate a battery profile BP based on the received battery information. That is, the profile obtaining unit 110 may obtain the battery profile BP by directly generating the battery profile M based on the battery information.

The section dividing step (S200) is a step of dividing a capacity section of the battery profile BP into a plurality of sections, and may be performed by the control unit 120.

Specifically, the control unit 120 may divide the entire capacity section of the battery profile BP into two or more sections. For example, in the embodiment of FIG. 2, the capacity sections of the battery profile BP are Qi to Qf. The control unit 120 may divide the capacity sections of Qi to Qf into the first section R1 and the second section R2 based on Qk.

The target value deriving step (S300) is a step of deriving a target value for any one target indicator among a plurality of diagnostic indicators preset in each section, and may be performed by the control unit 120.

For example, in the embodiment of FIG. 3, the control unit 120 may select a target indicator for each of the first section R1 and the second section R2. Then, control unit 120 may derive a target value corresponding to the selected target indicator.

The comparing step (S400) is a step of comparing the corresponding relationship between the derived plurality of target values with a reference profile preset to indicate the corresponding relationship between the plurality of target indicators, and may be performed by the control unit 120.

Specifically, it is assumed that the capacity section of the battery profile BP is divided into the first section R1 and the second section R2, the first target value for the target indicator is derived from the first section R1, and the second target value for the target indicator is derived from the second section R2. The control unit 120 may compare the target point representing the corresponding relationship of the plurality of target values with a reference profile.

For example, in the embodiment of FIG. 4, the control unit 120 may determine whether the target point is included in the reference profile. If the target point is not included in the reference profile, the control unit 120 may determine which region among the first region T1, the second region T2, and the third region T3 the target point is included in.

The diagnosing step (S500) is a step for diagnosing a state of the battery based on the comparison result, and may be performed by the control unit 120.

For example, in the embodiment of FIG. 4, the control unit 120 may diagnose the state of the battery as a positive/negative electrode degradation state if the target point is included in the reference profile.

As another example, the control unit 120 may diagnose the state of the battery as a negative electrode degradation state if the target point is included in the first region T1.

As still another example, the control unit 120 may diagnose the state of the battery as a positive electrode degradation state if the target point is included in the second region T2.

As still another example, the control unit 120 may diagnose the state of the battery as EOL state if the target point is included in third region T3.

The embodiments of the present disclosure described above may not be implemented only through an apparatus and a method, but may be implemented through a program that realizes a function corresponding to the configuration of the embodiments of the present disclosure or a recording medium on which the program is recorded. The program or recording medium may be easily implemented by those skilled in the art from the above description of the embodiments.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

Additionally, many substitutions, modifications and changes may be made to the present disclosure described hereinabove by those skilled in the art without departing from the technical aspects of the present disclosure, and the present disclosure is not limited to the above-described embodiments and the accompanying drawings, and each embodiment may be selectively combined in part or in whole to allow various modifications.

### EXPLANATION OF REFERENCE SIGNS

10: battery pack
11: battery
12: measuring unit
100: apparatus for diagnosing a battery
110: profile obtaining unit
120: control unit
130: storage unit
700: vehicle
710: battery pack

What is claimed is:

1. An apparatus for diagnosing a battery, comprising:
a profile obtaining unit configured to obtain a battery profile representing a corresponding relationship between voltage and capacity of the battery; and
a control unit configured to divide a capacity section of the battery profile into a plurality of sections, derive a target value for any one target indicator among a plurality of diagnostic indicators preset in each section, compare a corresponding relationship between the derived plurality of target values with a reference profile preset to represent a corresponding relationship between the plurality of target indicators, and diagnose a state of the battery based on the comparison result.

2. The apparatus for diagnosing the battery according to claim 1,
wherein the control unit is configured to:
diagnose the state of the battery as a positive/negative electrode degradation state when a target point representing the corresponding relationship between the plurality of target values is included in the reference profile,
diagnose the state of the battery as a negative electrode degradation state when the target point is included in a first region based on the reference profile, and
diagnose the state of the battery as a positive electrode degradation state when the target point is included in a second region based on the reference profile.

3. The apparatus for diagnosing the battery according to claim 2,
wherein the control unit is configured to diagnose the state of the battery as an end of life (EOL) state when the target point is included in a third region, and
wherein the third region is preset as a region that exceeds a preset threshold value for each of the plurality of target indicators.

4. The apparatus for diagnosing the battery according to claim 2,
wherein the control unit is configured to reduce at least one of an upper limit C-rate and a constant voltage charge time set for the battery when the state of the battery is diagnosed as the positive electrode degradation state or the positive/negative electrode degradation state.

5. The apparatus for diagnosing the battery according to claim 2,
wherein the control unit is configured to reduce a charge upper limit voltage set for the battery when the state of the battery is diagnosed as the negative electrode degradation state or the positive/negative electrode degradation state.

6. The apparatus for diagnosing the battery according to claim 1,
wherein the control unit is configured to divide the capacity section into a first section and a second section based on a preset division ratio or target capacity.

7. The apparatus for diagnosing the battery according to claim 6,
wherein the profile obtaining unit is configured to obtain a differential profile corresponding to the battery profile, and
wherein the control unit is configured to determine a main peak from the differential profile and divide the capacity section based on a capacity of the determined main peak.

8. The apparatus for diagnosing the battery according to claim 7,
wherein the differential profile represents a corresponding relationship between the capacity and a differential voltage of the battery, and
wherein the control unit is configured to determine a plurality of minimum points in the differential profile, and determine a minimum point with a smallest corresponding differential voltage as a main peak among the determined plurality of minimum points.

9. The apparatus for diagnosing the battery according to claim 7,
wherein the differential profile represents a corresponding relationship between the voltage and a differential capacity of the battery, and
wherein the control unit is configured to determine a plurality of maximum points in the differential profile, and determine a maximum point with a largest corresponding differential voltage as a main peak among the determined plurality of maximum points.

10. A battery pack, comprising the apparatus for diagnosing the battery according to claim 1.

11. A vehicle, comprising the apparatus for diagnosing the battery according to claim 1.

12. A method for diagnosing a battery, comprising:
obtaining a battery profile representing a corresponding relationship between voltage and capacity of a battery;
dividing a capacity section of the battery profile into a plurality of sections;
deriving a target value for any one target indicator among a plurality of diagnostic indicators preset in each section;
comparing a corresponding relationship between the derived plurality of target values with a reference profile preset to represent a corresponding relationship between the plurality of target indicators; and
diagnosing a state of the battery based on the comparison result.

13. The method for diagnosing the battery according to claim 1, comprising:
diagnosing the state of the battery as a positive/negative electrode degradation state when a target point representing the corresponding relationship between the plurality of target values is included in the reference profile,
diagnosing the state of the battery as a negative electrode degradation state when the target point is included in a first region based on the reference profile, and
diagnosing the state of the battery as a positive electrode degradation state when the target point is included in a second region based on the reference profile.

14. The method for diagnosing the battery according to claim 13, comprising:
diagnosing the state of the battery as an end of life (EOL) state when the target point is included in a third region,
wherein the third region is preset as a region that exceeds a preset threshold value for each of the plurality of target indicators.

15. The method for diagnosing the battery according to claim 13, comprising:
reducing at least one of an upper limit C-rate and a constant voltage charge time set for the battery when the state of the battery is diagnosed as the positive electrode degradation state or the positive/negative electrode degradation state.

16. The method for diagnosing the battery according to claim 13, comprising:
reducing a charge upper limit voltage set for the battery when the state of the battery is diagnosed as the negative electrode degradation state or the positive/negative electrode degradation state.

17. The method for diagnosing the battery according to claim 12, comprising:
dividing the capacity section into a first section and a second section based on a preset division ratio or target capacity.

18. The method for diagnosing the battery according to claim 17, comprising:
obtaining a differential profile corresponding to the battery profile, and
determining a main peak from the differential profile and dividing the capacity section based on a capacity of the determined main peak.

19. The method for diagnosing the battery according to claim 18,
wherein the differential profile represents a corresponding relationship between the capacity and a differential voltage of the battery, and
wherein the method further comprises determining a plurality of minimum points in the differential profile, and determining a minimum point with a smallest corresponding differential voltage as a main peak among the determined plurality of minimum points.

20. The method for diagnosing the battery according to claim 18,
wherein the differential profile represents a corresponding relationship between the voltage and a differential capacity of the battery, and
wherein the method further comprises determining a plurality of maximum points in the differential profile, and determining a maximum point with a largest corresponding differential voltage as a main peak among the determined plurality of maximum points.
